(19) United States
(12) Patent Application Publication
(10) Pub. No.: US 2015/0122469 A1
(43) Pub. Date: May 7, 2015

(54) FLUID DELIVERY SYSTEM FOR THERMAL TEST EQUIPMENT

(71) Applicants: Morten S. Jensen, Mesa, AZ (US); Todd R. Coons, Gilbert, AZ (US); Roland S. Muwanga, Calgary (CA)

(72) Inventors: Morten S. Jensen, Mesa, AZ (US); Todd R. Coons, Gilbert, AZ (US); Roland S. Muwanga, Calgary (CA)

(21) Appl. No.: 14/073,719

(22) Filed: Nov. 6, 2013

(51) Int. Cl. F28D 15/00; G01R 31/28

(52) U.S. Cl. CPC F28D 15/00; G01R 31/2851
USPC 165/168; 29/888.02

(57) ABSTRACT

Embodiments of the present disclosure are directed towards systems and apparatuses for delivery of thermal transfer fluid to and/or from a thermal head of thermal test equipment and for driving the thermal head and associated techniques. In one embodiment, a fluid delivery assembly includes a chamber assembly having an inlet channel and outlet channel for a thermal transfer fluid, and a piston assembly having an inlet channel and outlet channel for the thermal transfer fluid, the inlet channel of the piston assembly configured to route the thermal transfer fluid from the inlet channel of the chamber assembly and the outlet channel of the piston assembly configured to route the thermal transfer fluid to the outlet channel of the chamber assembly and a thermal head coupled with the piston assembly and configured to thermally couple with a device under test (DUT). Other embodiments may be described and/or claimed.

### FIELD

Embodiments of the present disclosure generally relate to the field of fluid delivery systems, and more particularly, to systems and apparatuses for delivery of thermal transfer fluid to and/or from a thermal head of thermal test equipment and for driving the thermal head and associated techniques.

### BACKGROUND

Presently, thermal test equipment may use hoses to deliver a thermal transfer fluid such as a coolant to a thermal head of the thermal test equipment coupled with a device under test (DUT) such as an integrated circuit (IC) assembly. However, weight of the hoses may generate undesirable mechanical moments at the thermal head, which may cause the thermal head to tilt and ultimately degrade a thermal contact pressure uniformity across the DUT. Additionally, an arrangement of hoses for a hose-based fluid delivery system may occupy substantial space in thermal test equipment and, thus, the hoses may require a portion of high cost area of an IC fabrication or test facility for operation. More compact designs may be desirable to save cost of valuable floor space. Fluid delivery systems that utilize traditional bellows designs may implement complex brazing technology, which may be prone to fatigue resulting in leaks.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cut-away perspective cross-section view of thermal test equipment, in accordance with some embodiments.

FIG. 2 schematically illustrates a cross-section side view free body diagram of a fluid delivery assembly, in accordance with some embodiments.

FIGS. 3a-c schematically illustrate cut-away perspective cross-section views of movement of a piston assembly of the fluid delivery assembly, in accordance with some embodiments.

FIG. 4 schematically illustrates a flow diagram for a method of fabricating thermal test equipment, in accordance with some embodiments.

FIG. 5 schematically illustrates a flow diagram for a method of using thermal test equipment, in accordance with some embodiments.

FIG. 6 schematically illustrates a computing device that includes various example components that may be thermally tested as a device under test (DUT) using thermal test equipment as described herein, in accordance with some embodiments.

### DETAILED DESCRIPTION

Embodiments of the present disclosure systems and apparatuses for delivery of thermal transfer fluid to and/or from a thermal head of thermal test equipment and for driving the thermal head and associated techniques. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

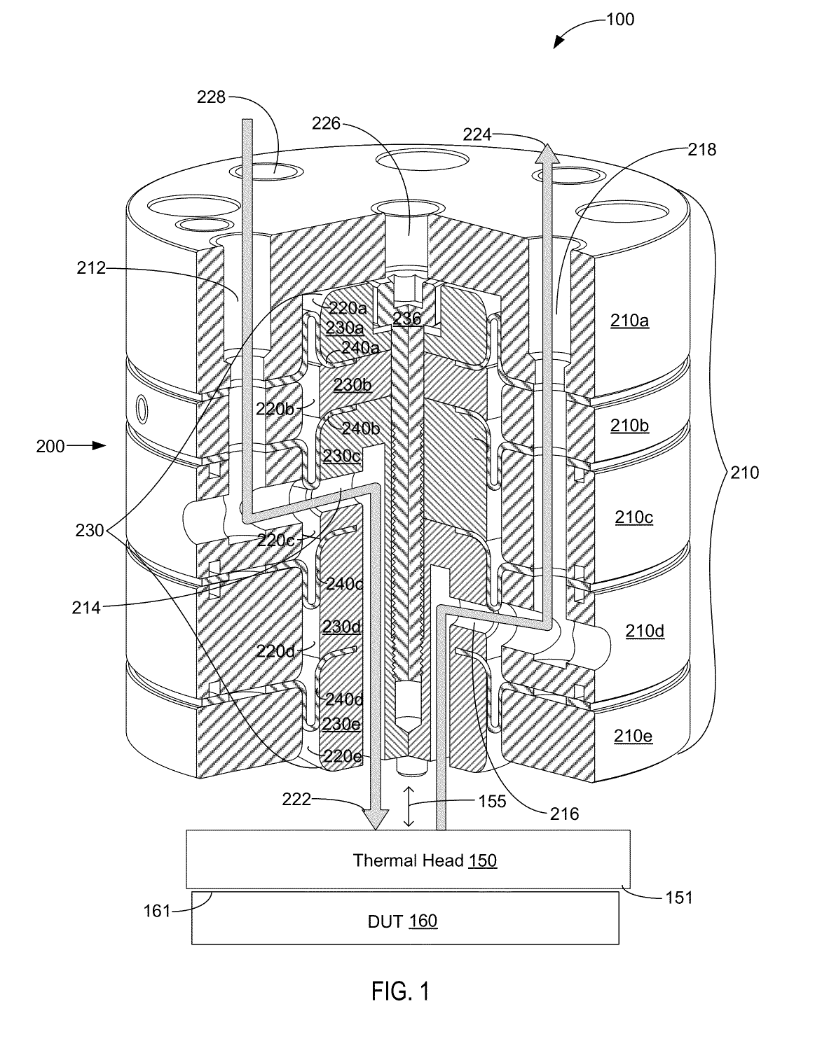

FIG. 1 schematically illustrates a cut-away perspective cross-section view of thermal test equipment 100, in accordance with some embodiments. The thermal test equipment 100 may include a fluid delivery assembly 200 coupled with a thermal head 150. The fluid delivery assembly 200 may be configured to route a thermal transfer fluid to and/or from the thermal head 150. The thermal transfer fluid may include, for example, a fluid (e.g., coolant) that removes heat from the thermal head 150 or a fluid that carries heat to the thermal head 150 and may include any of a variety of suitable liquids or gases. In one embodiment, for example, the thermal transfer fluid may be water.

In some embodiments, the fluid delivery assembly 200 may include a chamber assembly 210 coupled with a piston assembly 230. The chamber assembly 210 may be configured to house the piston assembly 230, in some embodiments, as can be seen. In the depicted configuration, the fluid delivery assembly 200 is cylindrical; however, subject matter is not limited in this regard and the fluid delivery assembly 200 may have any of a variety of other suitable shapes or profiles in other embodiments.

The chamber assembly 210 and the piston assembly 230 may each include one or more channels to route a thermal transfer fluid to and/or from the thermal head 150. For example, in the depicted embodiment, the chamber assembly 210 includes an inlet channel 212 configured to receive a thermal transfer fluid from facilities external to the chamber assembly 210. The inlet channel 212 of the chamber assembly 210 may be configured to route the thermal transfer fluid to an inlet channel 214 of the piston assembly 230 and the inlet channel 214 of the piston assembly 230 may be configured to route the thermal transfer fluid to the thermal head 150, as indicated by arrow 222. In some embodiments, an opening of the inlet channel 212 may be disposed on a top surface of the chamber assembly 210, as can be seen, to facilitate a more compact design of the thermal test equipment 100. Although only a single pathway (e.g., indicated by arrows 222, 224) is shown for delivery and removal the thermal transfer fluid in the depicted embodiment, the fluid delivery assembly 200 may include more pathways (e.g., more inlet channels and outlet channels) in other embodiments.

The thermal head 150 may be coupled with the piston assembly 230 using any suitable technique, according to various embodiments. For example, the thermal head may be coupled with the piston assembly 230 using a bolt-pattern and a face seal (gasket) to prevent leakage at an interface between the surfaces 151, 161. In some embodiments, the thermal head 150 may include one or more channels (not shown) corresponding with the one or more channels of the fluid delivery assembly 200 to receive the thermal transfer fluid from the inlet channel 214 of the piston assembly 230 and to route the thermal transfer fluid through the thermal head 150. In some embodiments, the thermal head 150 may be configured to route the thermal transfer fluid between the inlet channel 214 of the piston assembly 230 and an outlet channel 216 of the piston assembly. The thermal head 150 may include a surface 151 that is thermally coupled with the one or more channels of the thermal head 150 to allow the thermal transfer fluid to transfer thermal energy to or from a device under test (DUT) 160 by the thermal test equipment 100 when the fluid delivery assembly is in operation.

In some embodiments, the thermal head 150 may be configured to thermally couple with a DUT 160. For example, in some embodiments, the piston assembly 230 may be configured to drive the thermal head 150 to engage in thermal contact with the DUT 160. In some embodiments, the piston assembly 230 may apply a force between the thermal head 150 and the DUT 160 to facilitate transfer of thermal energy between a surface 151 of the thermal head 150 and a surface 161 of the DUT 160. In some embodiments, the piston assembly 230 may be configured to drive the thermal head 150 in an axial direction (e.g., as indicated by arrow 155) of the piston assembly 230 and/or chamber assembly 210, as can be seen.

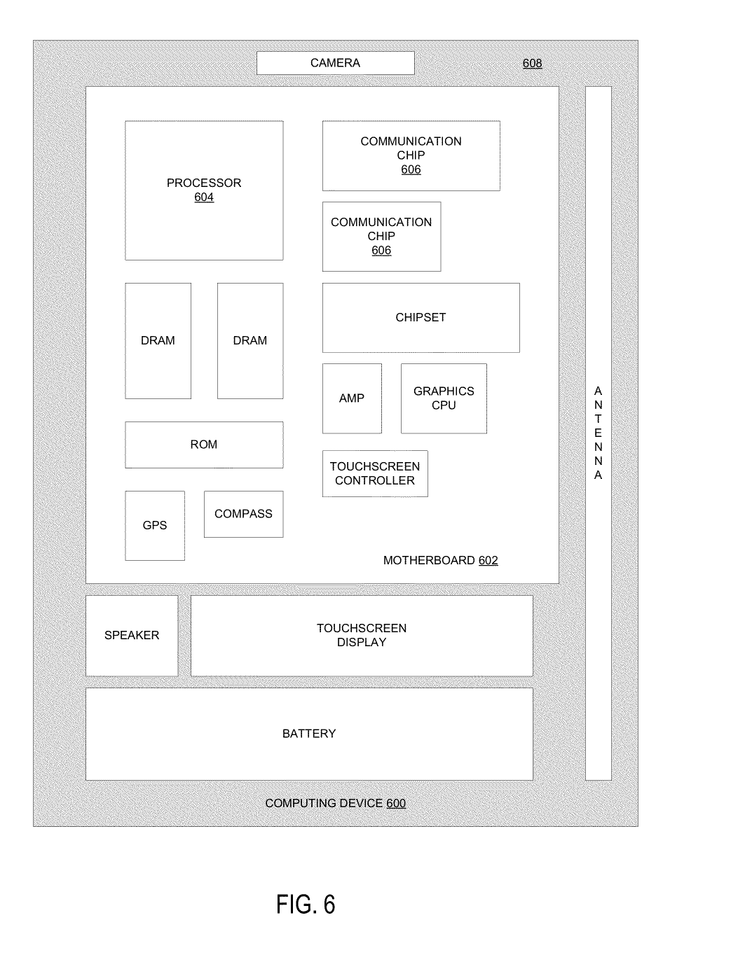

In some embodiments, the DUT 160 may be an electronic assembly. For example, the DUT 160 may be a semiconductor die or other IC assembly such as a heat spreader or other IC package component. The thermal test equipment 100 may be configured to increase, reduce or otherwise control a temperature of the DUT 160 according to a flow and/or temperature of the thermal transfer fluid through the thermal head 150. For example, the thermal test equipment 100 may be used in connection with a burn-in process of the DUT 160. Various examples of a device that may be a DUT 160 for thermal test by the thermal test equipment 100 are described further in connection with FIG. 6. The thermal test equipment 100 may be used to transfer heat according to principles described herein for suitable applications other than a DUT 160 in other embodiments.

In some embodiments, the outlet channel 216 of the piston assembly 230 may be configured to receive the thermal transfer fluid from the thermal head 150 and to route the thermal transfer fluid to an outlet channel 218 of the chamber assembly 210 (e.g., as indicated by arrow 224). The outlet channel 218 of the chamber assembly may route the thermal transfer fluid to facilities external to the fluid delivery assembly 200. In some embodiments, an opening of the outlet channel 218 may be disposed on a top surface of the chamber assembly 210, as can be seen, to facilitate a more compact design of the thermal test equipment 100.

According to various embodiments, the piston assembly 230 and the chamber assembly 210 may each be composed of multiple segments. The segments may be coupled together using any suitable means. Any suitable fastening mechanism such as, for example, a bolt 236 may be used to couple the segments of the piston assembly 230 together such that the segments are configured to move together when a load is applied on the piston assembly 230. The segments of the piston assembly 230 and the chamber assembly 210 may be used to separate or isolate pressures associated with routing the thermal transfer fluid through the fluid delivery assembly 200 from pressures associated with driving the piston assembly 230. For example, one or more barriers (hereinafter “diaphragms 240a-d”) may be disposed between individual segments of the piston assembly 230 and further disposed between individual segments of the chamber assembly 210 to isolate a pressure of a fluid within each chamber that is disposed between a segment of the piston assembly 230 and a corresponding segment of the chamber assembly 210. The diaphragms 240a-d may further allow the piston assembly 230 to move freely with little or no friction to allow displacement of the piston assembly 230/thermal head 150 while separating incoming thermal transfer fluid flow (e.g., inlet channels 212, 214), outgoing thermal transfer fluid flow (e.g., outlet channels 216, 218) and pneumatic pressure of a working fluid to provide a desirable DUT 160 contact force. In some embodiments, the diaphragms 240a-d may include one or more rolling diaphragms in a parallel configuration, as can be seen. In some embodiments, the diaphragms may be composed of a polymer such as, for example, a silicone-based polymer. The diaphragms 240a-d may include other suitable structures and/or materials in other embodiments.

In some embodiments, the piston assembly 230 and the chamber assembly 210 may be coupled together mechanically by the diaphragms 240a-d. For example, an inside of the diaphragms 240a-d may be used as face seals/gaskets between each individual segment of the piston assembly 230. An outside (e.g., flange) of the diaphragms 240a-d may be used as face seals/gaskets between each individual segment of the chamber assembly 210.

In the depicted embodiment, the piston assembly 230 includes a first segment 230a, second segment 230b, third segment 230c, fourth segment 230d and fifth segment 230e and the chamber assembly 210 includes a respective first segment 210a, second segment 210b, third segment 210c, fourth segment 210d and fifth segment 210e. The fluid delivery assembly 200 may include a diaphragm to separate each of the first segments 230a, 210a from the other segments (e.g., 230b-e, 210b-e), the second segments 230b, 210b from the other segments (e.g., 230a,c-e, 210a,c-e), the third segments 230c, 210c from the other segments (e.g., 230a-b,d-e, 210a-b,d-e), the fourth segments 230d, 210d from the other segments (e.g., 230a-c,e, 210a-c,e) and the fifth segments 230e, 210e from the other segments (e.g., 230a-d, 210a-d).

In some embodiments, a first diaphragm 240a may be disposed between the first segment 230a of the piston assembly 230 and the second segment 230b of the piston assembly 230 and extend between the first segment 210a of the chamber assembly 210 and the second segment 210b of the chamber assembly 210, as can be seen. In this manner, the first diaphragm 240a may be disposed between the first segment 230a of the piston assembly 230 and the chamber assembly 210 to form a first chamber 220a between the first segment 230a of the piston assembly 230 and the first segment 210a of the chamber assembly 210.

The first chamber 220a may be configured to receive and contain a working fluid that applies pressure (“piston pressure”) to drive the piston assembly 230 and thermal head 150 (e.g., in the axial direction indicated by 155) when in operation, according to various embodiments. The working fluid may include any of a variety of suitable gases or liquids. In one embodiment, the working fluid is air. In some embodiments, an opening of a channel 226 for the working fluid may be disposed on a top surface or a same surface as openings for the inlet channel 212 and outlet channel 218 for the thermal transfer fluid, as can be seen. Providing openings of the inlet channel 212, channel 226 and/or outlet channel 218 may allow a more compact design of the thermal test equipment 100 in a dimension perpendicular to the axial dimension, which may facilitate and allow reduced cost associated with higher density arrangements of the thermal test equipment 100.

In some embodiments, a second diaphragm 240b may be disposed between the second segment 230b of the piston assembly 230 and the third segment 230c of the piston assembly 230 and extend between the second segment 210b of the chamber assembly 210 and the third segment 210c of the chamber assembly 210, as can be seen. In this manner, the second diaphragm 240b may be disposed between the second segment 230b of the piston assembly 230 and the chamber assembly 210 to form a second chamber 220b between the second segment 230b of the piston assembly 230 and the second segment 210b of the chamber assembly 210.

The second chamber 220b may be configured to receive and contain a backpressure fluid, according to various embodiments. In this regard, the second chamber 220b may be referred to as a backpressure chamber. A pressure (“back pressure”) of the backpressure fluid in the second chamber 220b may be set to ensure that the diaphragms 240a, 240b, 240c and 240d have a positive back pressure to facilitate operation and reliability of the diaphragms 240a, 240b, 240c and 240d when the fluid delivery assembly 200 is in operation. For example, without the backpressure chamber, a piston pressure of the working fluid in the first chamber 220a would have to be greater than a pressure (“inlet pressure”) of the thermal transfer fluid in the inlet channels 212, 214 and third chamber 220c, which may further limit a design range of the piston pressure.

The backpressure fluid may include any of a variety of suitable gases or liquids. In one embodiment, the backpressure fluid is a same fluid as the working fluid in the first chamber 220a. The second diaphragm 240b may be configured to separate the working fluid and the backpressure fluid from the thermal transfer fluid. In some embodiments, the back pressure is greater than the piston pressure when the piston assembly 230 is in operation. In some embodiments, an opening of a channel 228 for the backpressure fluid may be disposed on the top surface of the chamber assembly 210, as can be seen, and may provide similar benefits with regards to compact design of the thermal test equipment 100 as previously described in connection with inlet channel 212, channel 226 and outlet channel 218.

In some embodiments, a third diaphragm 240c may be disposed between the third segment 230c of the piston assembly 230 and the fourth segment 230d of the piston assembly 230 and extend between the third segment 210c of the chamber assembly 210 and the fourth segment 210d of the chamber assembly 210, as can be seen. In this manner, the third diaphragm 240c may be disposed between the third segment 230c of the piston assembly 230 and the chamber assembly 210 to form a third chamber 220c between the third segment 230c of the piston assembly 230 and the third segment 210c of the chamber assembly 210.

The third chamber 220c may be configured to receive, contain and route the thermal transfer fluid from the inlet channel 212 of the chamber assembly 210 to the inlet channel 214 of the piston assembly 230, according to various embodiments. An effective pressure (e.g., inlet pressure) in the third chamber 220c may be configured to route the thermal transfer fluid through the inlet channels 212 to the thermal head 150.

In some embodiments, a fourth diaphragm 240d may be disposed between the fourth segment 230d of the piston assembly 230 and the fifth segment 230e of the piston assembly 230 and extend between the fourth segment 210d of the chamber assembly 210 and the fifth segment 210e of the chamber assembly 210, as can be seen. In this manner, the fourth diaphragm 240d may be disposed between the fourth segment 230d of the piston assembly 230 and the chamber assembly 210 to form a fourth chamber 220d between the fourth segment 230d of the piston assembly 230 and the fourth segment 210d of the chamber assembly 210.

The fourth chamber 220d may be configured to receive, contain and route the thermal transfer fluid from the outlet channel 216 of the piston assembly 230 to the outlet channel 218 of the chamber assembly 210, according to various embodiments. A pressure (“outlet pressure”) in the fourth chamber 220d may be configured to route the thermal transfer fluid through the outlet channels 216, 218 away from the thermal head 150. In some embodiments, the inlet pressure of the third chamber 220c may be greater than the outlet pressure of the fourth chamber 220d when the fluid delivery system is in operation.

According to various embodiments, the following pressure relationship [1] may exist in the fluid delivery assembly 200, when in operation, where Pₚᵢₛₜₒₙ is a piston pressure in the first chamber 220a, P_{back} is a back pressure in the second inlet is chamber 220b, Pᵢₙₗₑₜ is an inlet pressure in the third chamber 220c and Pₒᵤₜₗₑₜ is an outlet pressure in the fourth chamber 220d:

Pₚᵢₛₜₒₙ<P_{back}>Pᵢₙₗₑₜ>Pₒᵤₜₗₑₜ. [1]

The fourth diaphragm 240d may further separate the fourth chamber 220d from a fifth chamber 220e between the fifth segment 230e of the piston assembly 230 and the fifth segment 210e of the chamber assembly 210, as can be seen. In some embodiments, a pressure (“ambient pressure”) of the fifth chamber 220e may be atmospheric pressure.

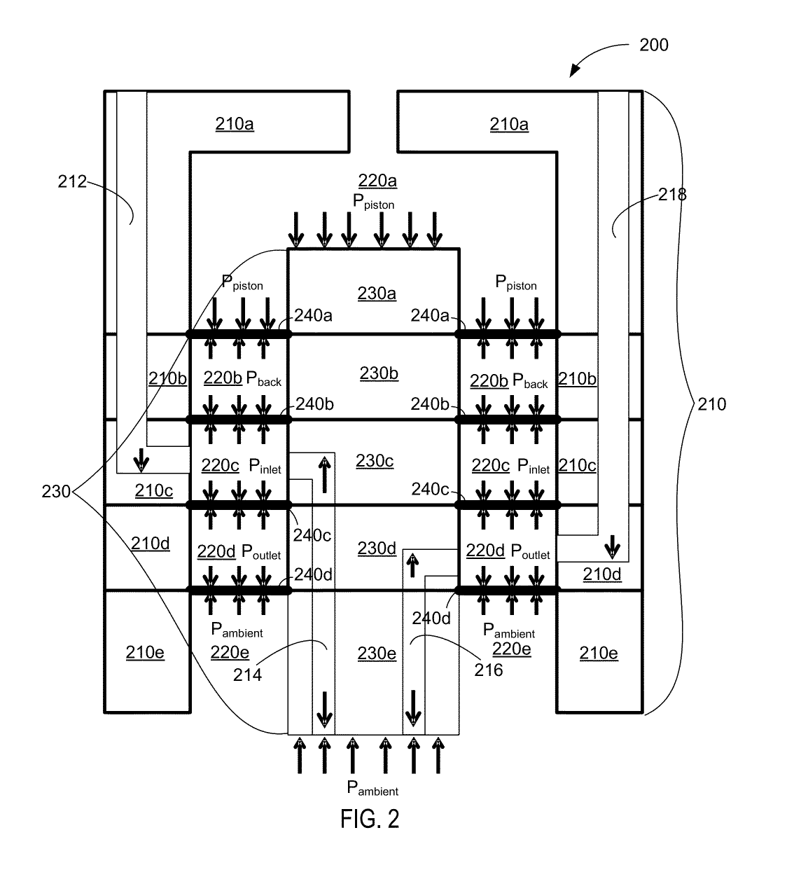

FIG. 2 schematically illustrates a cross-section side view free body diagram of a fluid delivery assembly 200, in accordance with some embodiments. In the free body diagram, pressure vectors are indicated by arrows for the piston pressure (Pₚᵢₛₜₒₙ) in the first chamber 220a, the back pressure (P_{back}) in the second chamber 220b, the inlet pressure (Pᵢₙₗₑₜ) in the third chamber 220c, the outlet pressure (Pₒᵤₜₗₑₜ) in the fourth chamber 220d, the ambient pressure (P_{ambient}) in the fifth chamber 220e, and inlet pressure in the inlet channels 212, 214 and outlet pressure in the outlet channels. Radial vectors are not depicted for simplicity.

In the free body diagram, it is assumed that effective pressure area is constant. That is, it is assumed that the effective pressure area does not change as a function of diaphragm displacement when the piston assembly 230 moves during operation. It is further assumed that all diaphragms 240a-d are identical, all segments 230a-e of the piston assembly 230 are joined together into a rigid assembly, all segments 210a-e of the chamber assembly are joined together and mounted to a rigid reference, inlet and outlet channels 212, 214, 216, 218 are redundant (e.g., symmetric, 180 degrees apart) in both segments 210a-e of the chamber assembly 210 and segments 230a-e of the piston assembly 230, the depicted embodiment only shows one internal channel flow, an internal thermal head (TH) pressure drop across the thermal head is expected to be symmetric and an effective force vector for the piston assembly 230 can be defined by the following relationship [2], where F_{eff, vertical} is an effective vertical force of the piston assembly 230, A_{eff} is an effective area:

F_{eff, vertical}=A_{eff}·(Pₚᵢₛₜₒₙ−P_{ambient}) [2]

Forces (e.g., F_{eff, vertical}) may be isolated in the fluid delivery assembly 200 through internal load balancing. For example, a load-balancing mechanism of one or more diaphragms (e.g., diaphragms 240a-d) may be used to isolate forces between the different chambers 220a, 220b, 220c, 220d, 220e. Load-balancing may be achieved by means of ensuring identical effective surface areas. Since the pressure in each chamber is substantially constant (e.g., spatial pressure gradients may be insignificant), the use of diaphragms 240a-d such as rolling diaphragms—which may have a contact effective axial area—may ensure that there are no resultant forces within each chamber. For example, a force acting on the top rolling diaphragm of a chamber may be identical to a force acting on a bottom rolling diaphragm of a chamber. In one embodiment, one or more of the diaphragms 240a-d may isolate or substantially isolate a force of pressure (e.g., Pᵢₙₗₑₜ, Pₒᵤₜₗₑₜ) for routing the thermal transfer fluid through the channels (e.g., channels 212, 214, 216, 218) from a force (e.g., Pₚᵢₛₜₒₙ) of driving a thermal head using a working fluid. According to various embodiments, the fluid delivery assembly 200 can supply thermal transfer fluid to a thermal head without biasing a loading mechanism (e.g., piston assembly 230) and further provides a delivery system that may be arranged in a higher density configuration than other fluid delivery systems (e.g., hose-based systems).

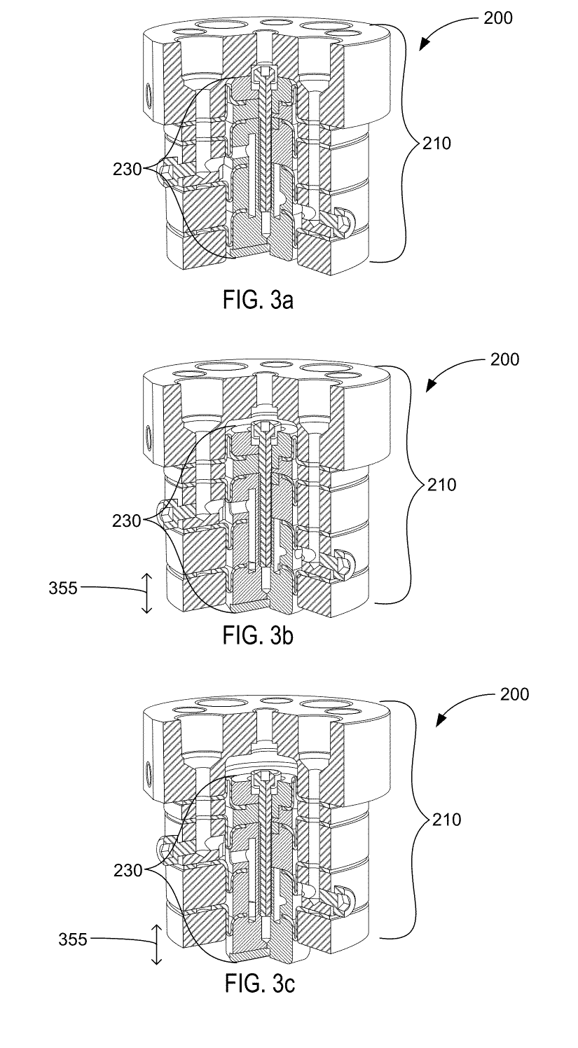

FIGS. 3a-c schematically illustrate cut-away perspective cross-section views of movement of a piston assembly 230 of the fluid delivery assembly 200, in accordance with some embodiments. FIGS. 3a-c may represent movement of the piston assembly 230 relative to the chamber assembly 210 as a function of increasing load (e.g., increasing piston pressure (Pₚᵢₛₜₒₙ). FIG. 3a depicts an example position of the piston assembly 230 with no load. FIG. 3b depicts an example position of the piston assembly 230 with ˜50% load. As can be seen in FIG. 3b, the piston assembly 230 has moved in a direction indicated by 355 relative to the chamber assembly 210. FIG. 3c depicts an example position of the piston assembly 230 with ˜100% load. As can be seen in FIG. 3c, the piston assembly 230 has moved further in the direction indicated by 355 relative to the chamber assembly 210. In some embodiments, the piston assembly 230 may provide a piston stroke of about 6 millimeters (˜¼ inch) with 100% load. The piston assembly 230 may extend other distances in other embodiments.

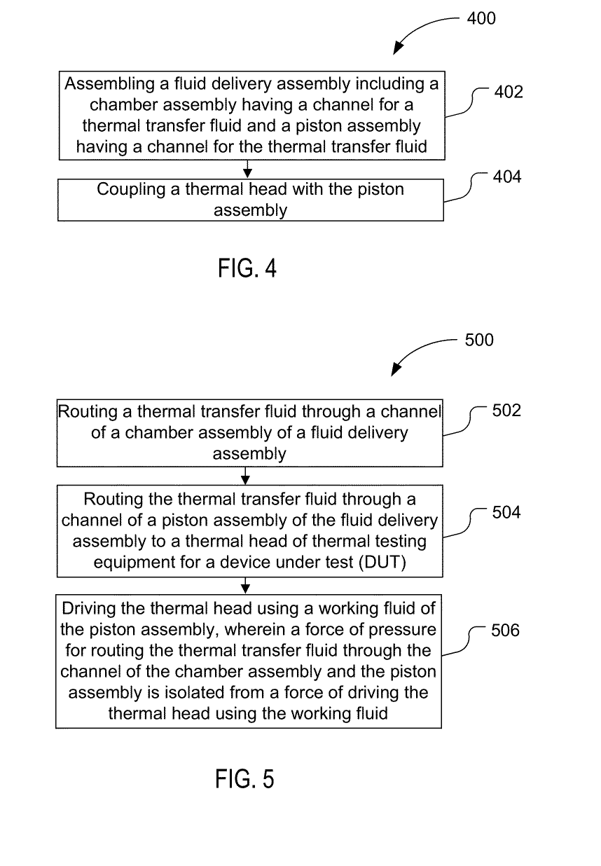

FIG. 4 schematically illustrates a flow diagram for a method of fabricating thermal test equipment (e.g., thermal test equipment 100 of FIG. 1), in accordance with some embodiments. At 402, the method 400 may include assembling a fluid delivery assembly (e.g., fluid delivery assembly 200 of FIGS. 1, 2 and/or 3a-c) including a chamber assembly (e.g., chamber assembly 210 of FIGS. 1, 2 and/or 3a-c) having a channel (e.g., one or more of channels 212, 218 of FIGS. 1, 2 and/or 3a-c) for a thermal transfer fluid and a piston assembly (e.g., piston assembly 230 of FIGS. 1, 2 and/or 3a-c) having a channel (e.g., one or more of channels 214, 216 of FIGS. 1, 2 and/or 3a-c) for the thermal transfer fluid. The fluid delivery assembly 200 may comport with embodiments described in FIGS. 1, 2 and/or 3a-c.

In some embodiments, assembling the fluid delivery assembly at 402 may include actions to arrange components as described herein. For example, assembling the fluid delivery assembly 200 may include forming a chamber assembly having an inlet channel and outlet channel for a thermal transfer fluid and forming the chamber assembly by coupling multiple segments together. Actions at 402 may further include forming a piston assembly having an inlet channel and outlet channel for a thermal transfer fluid and forming the piston assembly by coupling multiple segments together. In some embodiments, the piston assembly and chamber assembly may be coupled together such that the inlet channel of the piston assembly is configured to route the thermal transfer fluid from the inlet channel of the chamber assembly and the outlet channel of the piston assembly is configured to route the thermal transfer fluid to the outlet channel of the chamber assembly.

In some embodiments, assembling the delivery assembly at 402 may further include positioning a diaphragm between the piston assembly and the chamber assembly such that the diaphragm is configured to separate a thermal transfer fluid from a working fluid of the piston assembly. In some embodiments, positioning the diaphragm may include positioning a rolling diaphragm configured to isolate a force of pressure of the thermal transfer fluid from a force of the working fluid to drive the piston assembly when the piston assembly is in operation. In some embodiments, assembling the delivery assembly includes coupling segments of the piston assembly together and/or segments of the chamber assembly together and positioning diaphragms between the segments of the piston assembly and/or chamber assembly to provide separate chambers as described herein.

At 404, the method 404 comprises coupling a thermal head (e.g., thermal head 150 of FIG. 1) with the piston assembly. The thermal head may be coupled with the piston assembly using any suitable fastening means such that the inlet channel of the piston assembly is coupled with a respective inlet channel of the thermal head and the outlet channel of the piston assembly is coupled with a respective outlet channel of the thermal head. Multiple inlet and outlet channels of the piston assembly may be coupled with the thermal head in some embodiments.

FIG. 5 schematically illustrates a flow diagram for a method 500 of using thermal test equipment (e.g., thermal test equipment 100 of FIG. 1), in accordance with some embodiments. The method 500 may comport with techniques and configurations described in connection with FIGS. 1, 2 and 3a-c.

At 502, the method 500 may include routing a thermal transfer fluid through a channel of a chamber assembly of a fluid delivery assembly. In some embodiments, routing at 502 may include routing the thermal transfer fluid through an inlet channel and/or an outlet channel of the chamber assembly. Routing the thermal transfer fluid may be performed by applying an inlet pressure to the inlet channel of the chamber assembly and an outlet pressure to the outlet channel of the chamber assembly.

At 504, the method 500 may include routing the thermal transfer fluid through a channel of a piston assembly of the fluid delivery assembly to a thermal head of a thermal testing equipment for a device under test (DUT). The channel of the piston assembly may be coupled with the channel of the chamber assembly to receive the thermal transfer fluid from the chamber assembly. In some embodiments, routing at 504 may include routing the thermal transfer fluid through an inlet channel and/or an outlet channel of the piston assembly. Routing the thermal transfer fluid may be performed by applying an inlet pressure to the inlet channel of the chamber assembly and an outlet pressure to the outlet channel of the chamber assembly. In some embodiments, a same inlet pressure (e.g., Pᵢₙₗₑₜ) may be used to route the thermal transfer fluid through the channel of the chamber assembly and the channel of the piston assembly and/or a same outlet pressure (e.g., Pₒᵤₜₗₑₜ) may be used to route the thermal transfer fluid through the channel of the chamber assembly and the channel of the piston assembly. In some embodiments, routing the thermal transfer fluid may include routing a coolant.

At 506, the method 500 may include driving the thermal head using a working fluid of the piston assembly, wherein a force of pressure (e.g., Pᵢₙₗₑₜ and/or Pₒᵤₜₗₑₜ) for routing the thermal transfer fluid through the channel of the chamber assembly and the piston assembly is isolated or substantially isolated from a force (e.g., Pₚᵢₛₜₒₙ) of driving the thermal head using the working fluid. In some embodiments, the forces may be isolated by a load-balancing mechanism of one or more diaphragms that are disposed between the piston assembly and the chamber assembly and configured to separate the thermal transfer fluid from the working fluid of the piston assembly. In some embodiments, driving the thermal head using a working fluid may include using a gas such as air.

Various operations are described as multiple discrete operations in turn, in a manner that is most helpful in understanding the claimed subject matter. However, the order of description should not be construed as to imply that these operations are necessarily order dependent. For example, actions of the methods 400 or 500 may be performed in another suitable order than depicted.

Embodiments of the present disclosure may be implemented into a system using any suitable hardware and/or software to configure as desired. FIG. 6 schematically illustrates a computing device 600 that includes various example components that may be thermally tested as a device under test (e.g., DUT 160 of FIG. 1) using thermal test equipment (e.g., thermal test equipment 100 of FIG. 1) as described herein, in accordance with some embodiments. The computing device 600 may house a board such as motherboard 602 (e.g., in housing 608). The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In further implementations, the communication chip 606 may be part of the processor 604. Any of the processor 604, communication chip 606, motherboard 602 or other devices of computing device 600 described below may be a DUT as described in connection with FIG. 1.

Depending on its applications, computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 606 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other embodiments.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 may be packaged in an IC package assembly. The term “processor” may refer to any device or portion of a device that processes electronic data from registers and/or memory to transform that electronic data into other electronic data that may be stored in registers and/or memory.

The communication chip 606 may also include a die that may be packaged in an IC package assembly as described herein. In further implementations, another component (e.g., memory device or other integrated circuit device) housed within the computing device 600 may include a die that may be packaged in an IC package assembly as described herein.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 600 may be a mobile computing device in some embodiments. In further implementations, the computing device 600 may be any other electronic device that processes data.

### Examples

According to various embodiments, the present disclosure describes an apparatus (e.g., thermal test equipment). Example 1 of the apparatus includes a fluid delivery assembly including a chamber assembly having an inlet channel and outlet channel for a thermal transfer fluid, and a piston assembly having an inlet channel and outlet channel for the thermal transfer fluid, the inlet channel of the piston assembly configured to route the thermal transfer fluid from the inlet channel of the chamber assembly and the outlet channel of the piston assembly configured to route the thermal transfer fluid to the outlet channel of the chamber assembly and a thermal head coupled with the piston assembly and configured to thermally couple with a device under test (DUT), wherein the thermal head is configured to route the thermal transfer fluid between the inlet channel of the piston assembly and the outlet channel of the piston assembly and the piston assembly is configured to drive the thermal head. Example 2 may include the apparatus of Example 1, wherein the fluid delivery assembly further comprises a diaphragm disposed between the piston assembly and the chamber assembly, wherein the diaphragm is configured to separate the thermal transfer fluid from a working fluid of the piston assembly. Example 3 may include the apparatus of Example 2, wherein the diaphragm is a rolling diaphragm configured to isolate a force of pressure of the thermal transfer fluid from a force of the working fluid to drive the piston assembly when the piston assembly is in operation. Example 4 may include the apparatus of Example 2, wherein the piston assembly includes a first segment, a second segment disposed adjacent to the first segment and a third segment disposed adjacent to the second segment and the diaphragm is a second diaphragm disposed between the second segment and the third segment to form a second chamber between the first segment and the chamber assembly and the fluid delivery assembly further comprises a first diaphragm disposed between the first segment and the chamber assembly and further disposed between the first segment and the second segment to form a first chamber between the first segment and the chamber assembly. Example 5 may include the apparatus of Example 4, wherein the first chamber is configured to receive the working fluid the second chamber is configured to receive a backpressure fluid; and a pressure of the second chamber is greater than a pressure of the first chamber when the piston assembly is in operation. Example 6 may include the apparatus of any of Examples 4-5, wherein the piston assembly further comprises a fourth segment adjacent to the third segment and a fifth segment adjacent to the fourth segment and the fluid delivery assembly further comprises a third diaphragm disposed between the third segment and the chamber assembly and further disposed between the third segment and the fourth segment to form a third chamber between the third segment and the chamber assembly and a fourth diaphragm disposed between the fourth segment and the chamber assembly and further disposed between the fourth segment and the fifth segment to form a fourth chamber between the fourth segment and the chamber assembly. Example 7 may include the apparatus of Example 6, wherein the third chamber is configured to receive the thermal transfer fluid from the inlet channel of the chamber assembly, the fourth chamber is configured to receive the thermal transfer fluid from the outlet channel of the piston assembly and a pressure of the third chamber is greater than a pressure of the fourth chamber when the fluid delivery system is in operation. Example 8 may include the apparatus of Example 6 or 7, further comprising a fastening mechanism to mechanically couple the first segment, the second segment, the third segment and the fourth segment of the piston assembly together. Example 9 may include the apparatus of any of Examples 1-8, wherein the piston assembly is housed within the chamber assembly. Example 10 may include the apparatus of any of Examples 1-9, wherein the chamber assembly has an axial dimension and the piston assembly is configured to drive the thermal head in the axial dimension.

According to various embodiments, the present disclosure describes a method of fabricating an apparatus (e.g., fluid delivery assembly and/or thermal test equipment). Example 11 of the method includes assembling a fluid delivery assembly including a chamber assembly having an inlet channel and outlet channel for a thermal transfer fluid, and a piston assembly having an inlet channel and outlet channel for the thermal transfer fluid, the inlet channel of the piston assembly configured to route the thermal transfer fluid from the inlet channel of the chamber

assembly and the outlet channel of the piston assembly configured to route the thermal transfer fluid to the outlet channel of the chamber assembly and coupling a thermal head with the piston assembly, the thermal head configured to thermally couple with a device under test (DUT), wherein the thermal head is configured to route the thermal transfer fluid between the inlet channel of the piston assembly and the outlet channel of the piston assembly and the piston assembly is configured to drive the thermal head. Example 12 may include the method of Example 11, wherein assembling the fluid delivery assembly further comprises positioning a diaphragm between the piston assembly and the chamber assembly, wherein the diaphragm is configured to separate the thermal transfer fluid from a working fluid of the piston assembly. Example 13 may include the method of Example 12, wherein positioning the diaphragm comprises positioning a rolling diaphragm configured to isolate a force of pressure of the thermal transfer fluid from a force of the working fluid to drive the piston assembly when the piston assembly is in operation. Example 14 may include the method of Example 12, wherein assembling the fluid delivery assembly further comprises coupling a first segment of the piston assembly with a second segment of the piston assembly, coupling a third segment of the piston assembly with the second segment of the piston assembly, wherein the diaphragm is a second diaphragm disposed between the second segment and the third segment to form a second chamber between the first segment and the chamber assembly and positioning a first diaphragm between the first segment and the chamber assembly and further between the first segment and the second segment to form a first chamber between the first segment and the chamber assembly. Example 15 may include the method of Example 14, wherein assembling the fluid delivery assembly further comprises coupling a fourth segment of the piston assembly with the third segment and coupling a fifth segment of the piston assembly with the fourth segment and positioning a third diaphragm between the third segment and the chamber assembly and further between the third segment and the fourth segment to form a third chamber between the third segment and the chamber assembly and positioning a fourth diaphragm between the fourth segment and the chamber assembly and further between the fourth segment and the fifth segment to form a fourth chamber between the fourth segment and the chamber assembly.

According to various embodiments, the present disclosure describes a method of using an apparatus (e.g., thermal test equipment and/or fluid delivery assembly). Example 16 of the method includes routing a thermal transfer fluid through a channel of a chamber assembly of a fluid delivery assembly and routing the thermal transfer fluid through a channel of a piston assembly of the fluid delivery assembly to a thermal head of thermal test equipment for a device under test (DUT), wherein the channel of the piston assembly is coupled with the channel of the chamber assembly and driving the thermal head using a working fluid of the piston assembly, wherein a force of pressure for routing the thermal transfer fluid through the channel of the chamber assembly and the piston assembly is substantially isolated from a force of driving the thermal head using the working fluid. Example 17 may include the method of Example 16, wherein the force of pressure for routing the thermal transfer fluid through the channel of the chamber assembly and the piston assembly is substantially isolated from the force of driving the thermal head using the working fluid by a load-balancing mechanism of one or more diaphragms that are disposed between the piston assembly and the chamber assembly and configured to separate the thermal transfer fluid from the working fluid of the piston assembly. Example 18 may include the method of Example 17, wherein routing the thermal transfer fluid through the channel of the chamber assembly comprises routing the thermal transfer fluid through an inlet channel and an outlet channel of the chamber assembly, routing the thermal transfer fluid through the channel of the piston assembly comprises routing the thermal transfer fluid through an inlet channel and an outlet channel of the piston assembly and the inlet channel of the piston assembly is configured to receive the thermal transfer fluid from the inlet channel of the chamber assembly. Example 19 may include the method of Example 18, wherein the thermal head is configured to receive the thermal transfer fluid from the inlet channel of the piston assembly and output the thermal transfer fluid to the outlet channel of the piston assembly and the outlet channel of the chamber assembly is configured to receive the thermal transfer fluid from the outlet channel of the piston assembly. Example 20 may include the method of any of Examples 16-19, wherein routing the thermal transfer fluid through the channel of the chamber assembly and the piston assembly comprises routing a coolant and driving the thermal head using a working fluid comprises driving the thermal head using a gas.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. An apparatus comprising:
a fluid delivery assembly including
a chamber assembly having an inlet channel and outlet channel for a thermal transfer fluid, and
a piston assembly having an inlet channel and outlet channel for the thermal transfer fluid, the inlet channel of the piston assembly configured to route the thermal transfer fluid from the inlet channel of the chamber assembly and the outlet channel of the piston assembly configured to route the thermal transfer fluid to the outlet channel of the chamber assembly; and
a thermal head coupled with the piston assembly and configured to thermally couple with a device under test (DUT), wherein the thermal head is configured to route the thermal transfer fluid between the inlet channel of the piston assembly and the outlet channel of the piston assembly and the piston assembly is configured to drive the thermal head.

2. The apparatus of claim 1, wherein the fluid delivery assembly further comprises:
a diaphragm disposed between the piston assembly and the chamber assembly, wherein the diaphragm is configured to separate the thermal transfer fluid from a working fluid of the piston assembly.

3. The apparatus of claim 2, wherein the diaphragm is a rolling diaphragm configured to isolate a force of pressure of the thermal transfer fluid from a force of the working fluid to drive the piston assembly when the piston assembly is in operation.

4. The apparatus of claim 2, wherein:
the piston assembly includes a first segment, a second segment disposed adjacent to the first segment and a third segment disposed adjacent to the second segment; and
the diaphragm is a second diaphragm disposed between the second segment and the third segment to form a second chamber between the first segment and the chamber assembly; and
the fluid delivery assembly further comprises:
a first diaphragm disposed between the first segment and the chamber assembly and further disposed between the first segment and the second segment to form a first chamber between the first segment and the chamber assembly.

5. The apparatus of claim 4, wherein:
the first chamber is configured to receive the working fluid;
the second chamber is configured to receive a backpressure fluid; and
a pressure of the second chamber is greater than a pressure of the first chamber when the piston assembly is in operation.

6. The apparatus of claim 4, wherein:
the piston assembly further comprises a fourth segment adjacent to the third segment and a fifth segment adjacent to the fourth segment; and
the fluid delivery assembly further comprises:
a third diaphragm disposed between the third segment and the chamber assembly and further disposed between the third segment and the fourth segment to form a third chamber between the third segment and the chamber assembly; and
a fourth diaphragm disposed between the fourth segment and the chamber assembly and further disposed between the fourth segment and the fifth segment to form a fourth chamber between the fourth segment and the chamber assembly.

7. The apparatus of claim 6, wherein:
the third chamber is configured to receive the thermal transfer fluid from the inlet channel of the chamber assembly;
the fourth chamber is configured to receive the thermal transfer fluid from the outlet channel of the piston assembly; and
a pressure of the third chamber is greater than a pressure of the fourth chamber when the fluid delivery system is in operation.

8. The apparatus of claim 6, further comprising a fastening mechanism to mechanically couple the first segment, the second segment, the third segment and the fourth segment of the piston assembly together.

9. The apparatus of claim 1, wherein the piston assembly is housed within the chamber assembly.

10. The apparatus of claim 9, wherein:
the chamber assembly has an axial dimension; and
the piston assembly is configured to drive the thermal head in the axial dimension.

11. A method of comprising:
assembling a fluid delivery assembly including
a chamber assembly having an inlet channel and outlet channel for a thermal transfer fluid, and
a piston assembly having an inlet channel and outlet channel for the thermal transfer fluid, the inlet channel of the piston assembly configured to route the thermal transfer fluid from the inlet channel of the chamber assembly and the outlet channel of the piston assembly configured to route the thermal transfer fluid to the outlet channel of the chamber assembly; and
coupling a thermal head with the piston assembly, the thermal head configured to thermally couple with a device under test (DUT), wherein the thermal head is configured to route the thermal transfer fluid between the inlet channel of the piston assembly and the outlet channel of the piston assembly and the piston assembly is configured to drive the thermal head.

12. The method of claim 11, wherein assembling the fluid delivery assembly further comprises:
positioning a diaphragm between the piston assembly and the chamber assembly, wherein the diaphragm is configured to separate the thermal transfer fluid from a working fluid of the piston assembly.

13. The method of claim 12, wherein positioning the diaphragm comprises positioning a rolling diaphragm configured to isolate a force of pressure of the thermal transfer fluid from a force of the working fluid to drive the piston assembly when the piston assembly is in operation.

14. The method of claim 12, wherein assembling the fluid delivery assembly further comprises:
coupling a first segment of the piston assembly with a second segment of the piston assembly;
coupling a third segment of the piston assembly with the second segment of the piston assembly, wherein the diaphragm is a second diaphragm disposed between the second segment and the third segment to form a second chamber between the first segment and the chamber assembly; and
positioning a first diaphragm between the first segment and the chamber assembly and further between the first segment and the second segment to form a first chamber between the first segment and the chamber assembly.

15. The method of claim 14, wherein assembling the fluid delivery assembly further comprises:
coupling a fourth segment of the piston assembly with the third segment and coupling a fifth segment of the piston assembly with the fourth segment; and
positioning a third diaphragm between the third segment and the chamber assembly and further between the third segment and the fourth segment to form a third chamber between the third segment and the chamber assembly; and
positioning a fourth diaphragm between the fourth segment and the chamber assembly and further between the fourth segment and the fifth segment to form a fourth chamber between the fourth segment and the chamber assembly.

16. A method comprising:
routing a thermal transfer fluid through a channel of a chamber assembly of a fluid delivery assembly; and
routing the thermal transfer fluid through a channel of a piston assembly of the fluid delivery assembly to a thermal head of thermal test equipment for a device under test (DUT), wherein the channel of the piston assembly is coupled with the channel of the chamber assembly; and
driving the thermal head using a working fluid of the piston assembly, wherein a force of pressure for routing the thermal transfer fluid through the channel of the chamber assembly and the piston assembly is substantially isolated from a force of driving the thermal head using the working fluid.

17. The method of claim 16, wherein:
the force of pressure for routing the thermal transfer fluid through the channel of the chamber assembly and the piston assembly is substantially isolated from the force of driving the thermal head using the working fluid by a load-balancing mechanism of one or more diaphragms that are disposed between the piston assembly and the chamber assembly and configured to separate the thermal transfer fluid from the working fluid of the piston assembly.

18. The method of claim 17, wherein:
routing the thermal transfer fluid through the channel of the chamber assembly comprises routing the thermal transfer fluid through an inlet channel and an outlet channel of the chamber assembly;
routing the thermal transfer fluid through the channel of the piston assembly comprises routing the thermal transfer fluid through an inlet channel and an outlet channel of the piston assembly; and
the inlet channel of the piston assembly is configured to receive the thermal transfer fluid from the inlet channel of the chamber assembly.

19. The method of claim 18, wherein:
the thermal head is configured to receive the thermal transfer fluid from the inlet channel of the piston assembly and output the thermal transfer fluid to the outlet channel of the piston assembly; and
the outlet channel of the chamber assembly is configured to receive the thermal transfer fluid from the outlet channel of the piston assembly.

20. The method of claim 16, wherein:
routing the thermal transfer fluid through the channel of the chamber assembly and the piston assembly comprises routing a coolant; and
driving the thermal head using a working fluid comprises driving the thermal head using a gas.
